(19) United States
(12) Patent Application Publication
(10) Pub. No.: US 2009/0269879 A1
(43) Pub. Date: Oct. 29, 2009

(54) Metalorganic Chemical Vapor Deposition of Zinc Oxide

(75) Inventors: Bunmi T. Adekore, Arlington, MA (US); Jonathan Pierce, Piscataway, NJ (US)

Correspondence Address: Sunstein Kann Murphy & Timbers LLP, 125 SUMMER STREET, BOSTON, MA, 02110-1618, US

(73) Assignee: LUMENZ, INC., Boston, MA (US)

(21) Appl. No.: 12/421,133

(22) Filed: Apr. 9, 2009

Related U.S. Application Data
(60) Provisional application No. 61/048,024, filed on Apr. 25, 2008.

(51) Int. Cl. H01L 21/365; C23C 16/00

(52) U.S. Cl. 438/104; 118/722; 257/E21.463

(57) ABSTRACT

A method of metalorganic chemical vapor deposition includes converting a condensed matter source to provide a first gas, the source including at least one element selected from the group consisting of gold, silver and potassium. The method further includes providing a second gas comprising zinc and a third gas comprising oxygen, transporting the first gas, the second gas, and the third gas to a substrate, and forming a p-type zinc-oxide based semiconductor layer on the substrate.

### CROSS-REFERENCE TO RELATED APPLICATIONS

This patent application claims priority to U.S. Provisional Patent Application No. 61/048,024 filed Apr. 25, 2008, entitled METALORGANIC CHEMICAL VAPOR DEPOSITION OF ZINC OXIDE, the disclosure of which is incorporated by reference herein in its entirety.

### FIELD OF THE INVENTION

The invention generally relates to metalorganic chemical vapor deposition and, more particularly, the invention relates to metalorganic chemical vapor deposition of p-type zinc oxide.

### BACKGROUND OF THE INVENTION

Chemical vapor deposition (CVD) is a deposition process that is used to form thin films on a substrate, such as a wafer. In a CVD process, a substrate is exposed to one or more precursors in a reaction chamber. The substrate is typically heated to a temperature higher than the decomposition temperature of the precursor so that when the precursor contacts the substrate it reacts with or decomposes onto the surface of the substrate to produce the desired thin film. During this process, byproducts are also produced, some of which are unintentionally incorporated into the film. In some cases, these incorporated byproducts are impurities that detrimentally affect the film or its function.

Currently, there are several different types of CVD processes, which differ primarily by the process conditions used, e.g., low pressure, plasma enhanced, plasma assisted, etc. Metalorganic chemical vapor deposition (MOCVD) is any of the CVD processes which use metalorganic precursors. Some metals, however, such as heavy metals, are difficult to transport and/or do not have readily available gas sources. Thus, these kinds of metals are seldom deposited by MOCVD.

### SUMMARY OF THE INVENTION

In accordance with one embodiment of the invention, a method of metalorganic chemical vapor deposition includes converting a condensed matter source to provide a first gas, the source including at least one element selected from the group consisting of gold, silver and potassium. The method further includes providing a second gas comprising zinc and a third gas comprising oxygen, transporting the first gas, the second gas, and the third gas to a substrate, and forming a p-type zinc-oxide based semiconductor layer on the substrate.

In accordance with related embodiments of the invention, the condensed matter source may be a non-halogenated and non-silylated source. The non-halogenated and non-silylated condensed matter source may be in a solid phase, and converting may include subliming the source. The source may have a vapor pressure ranging from about 10⁻⁵ to about 10³ torr between about 30° C. to about 300° C. Transporting the first gas may include heating transport lines of the first gas to a temperature of about the source's sublimation temperature or greater. The source may include a polymerization inhibitor and the polymerization inhibitor may include inert particles. The source may be a powder interspersed with the inert particles and the inert particles may have a size distribution that is of the same order of magnitude as that of the powder.

Further, the source may be a liquid or a gel and the inert particles may be suspended in the liquid or the gel. The polymerization inhibitor may be selected from the group consisting of quinones and oxygen. The method may further include providing a fourth gas including a surfactant that reacts with the first gas. The fourth gas may be transported to the substrate along with the first gas, the second gas, and the third gas. The surfactant may include boron. The condensed matter source may include a halogen or silicon. The condensed matter source may be in a solid phase, and converting may include subliming the source. The source may have a vapor pressure ranging from about 10⁻⁵ to about 10³ torr between about 30° C. and about 300° C. The substrate may be heated in an elevated temperature environment between about 700° C. to about 850° C.

The method may further include annealing the p-type zinc-oxide based semiconductor layer in an elevated temperature environment for a period of time so that at least a portion of the halogen or silicon diffuses out of the layer. The elevated temperature environment may be between about 500° C. to about 1400° C., or between about 900° C. to about 1100° C. and the period of time may be greater than about 1 hour. Annealing may be performed at a pressure ranging from about 0.1 mbar to about 2.4 kbar. The annealing may be performed in an ambient that includes at least one selected from the group consisting of an inert gas, air, and oxygen. The substrate may include a first surface and a second surface, and forming a p-type zinc-oxide based semiconductor layer may occur on the first surface. The method may further include abrading the second surface of the substrate, and annealing the substrate in an elevated temperature environment for a period of time so that at least a portion of the halogen or silicon diffuses away from the first surface towards the second surface.

In accordance with another embodiment of the invention, a method of depositing a p-type zinc-oxide based semiconductor layer onto a substrate by a metalorganic chemical vapor deposition technique includes converting a non-halogenated and non-silylated condensed matter source to a first gas that provides a p-type dopant, wherein the condensed matter source includes at least one element selected from the group consisting of gold, silver, and potassium and has a vapor pressure ranging from about 10⁻⁵ to about 10³ torr between about 30° C. and about 300° C. The method further includes supplying reaction gases including the first gas, a second gas comprising zinc, and a third gas comprising oxygen, and transporting the reaction gases to a surface of a substrate to grow the p-type zinc-oxide based semiconductor layer.

In accordance with another embodiment of the invention, a method of forming a p-type zinc-oxide based semiconductor layer by metalorganic chemical vapor deposition includes converting a condensed matter source to provide a first gas comprising a halogen or silicon, the source including at least one element selected from the group consisting of gold, silver, and potassium. The method further includes providing a second gas comprising zinc and a third gas comprising oxygen, transporting the first gas, the second gas, and the third gas to the substrate to form a zinc-oxide based film, and annealing the zinc-oxide based film in an elevated temperature environment for a period of time so that at least a portion of the halogen or silicon diffuses out of the film to produce the p-type zinc-oxide based semiconductor layer.

In accordance with another embodiment of the invention, a method of forming a p-type zinc-oxide based semiconductor layer on a substrate by metalorganic chemical vapor deposition includes heating the substrate in an elevated temperature environment between about 700° C. to about 850° C. and converting a condensed matter source to provide a first gas comprising a halogen or silicon, the source including at least one element selected from the group consisting of gold, silver, and potassium. The method further includes providing a second gas comprising zinc and a third gas comprising oxygen and transporting the first gas, the second gas, and the third gas to a surface of the substrate to grow the p-type zinc-oxide based semiconductor layer.

In accordance with another embodiment of the invention, a method of metalorganic chemical vapor deposition includes converting a condensed matter source to provide a first gas, the source including at least one p-type dopant element. The method further includes providing a second gas comprising zinc and a third gas comprising oxygen, transporting the first gas, the second gas, and the third gas to a substrate, and forming a p-type zinc-oxide based semiconductor layer on the substrate. In accordance with related embodiments of the invention, the p-type dopant element may include at least one element selected from the group consisting of gold, silver, and potassium.

In accordance with another embodiment of the invention, a metalorganic chemical vapor deposition system includes a condensed matter source having at least one p-type dopant element. The system further includes a first source comprising zinc, a second source comprising oxygen, and a chemical vapor deposition reactor chamber connected to the condensed matter source, the first source, and the second source. The system also includes a heated transport line connecting the condensed matter source to the chemical vapor deposition reactor chamber. In accordance with related embodiments of the invention, the system may further include a heater containing the condensed matter source. In accordance with related embodiments, the at least one p-type dopant element may be selected from the group consisting of gold, silver, and potassium.

### BRIEF DESCRIPTION OF THE DRAWINGS

The foregoing and advantages of the invention will be appreciated more fully from the following further description thereof with reference to the accompanying drawings wherein:

FIG. 1 schematically shows an illustrative metalorganic chemical vapor deposition system according to embodiments of the present invention; and

FIG. 2 shows a metalorganic chemical vapor deposition process according to embodiments of the present invention.

### DESCRIPTION OF ILLUSTRATIVE EMBODIMENTS

Various embodiments of the present invention describe a system and method of metalorganic chemical vapor deposition (MOCVD) of p-type zinc oxide (ZnO) using a condensed matter source for the p-type dopant. In zinc oxide, a p-type dopant acts as an active acceptor in the ZnO crystals. Some kinds of p-type dopants, such as silver (Ag), gold (Au) and/or potassium (K), may be limited by the unavailability of volatile species using conventional metalorganic transport temperatures (e.g., ≦30° C.) and equipment.

In addition, the potential source materials that may be used for these kinds of p-type dopants, (e.g., halogenated or silylated materials) may incorporate other, unwanted constituent elements into the film that are detrimental to the p-type ZnO. For example, hydrogen, silicon and the halogens are active donors in ZnO so the incorporation of these constituents into the film reduces or compensates for the p-type dopant acceptors introduced during the MOCVD process. The realization of p-type conductivity in ZnO epitaxial layers typically requires atomic concentrations of the selected acceptor within about 10¹⁵-10²² cm⁻³. In order to achieve a net incorporation of acceptors, the incorporated acceptor concentration should exceed that of the unintentionally incorporated compensating donor species. Embodiments of the present invention provide a variety of ways of reducing or eliminating the potential unwanted incorporation of these kinds of active donors into the ZnO film. Details of illustrative embodiments are discussed below.

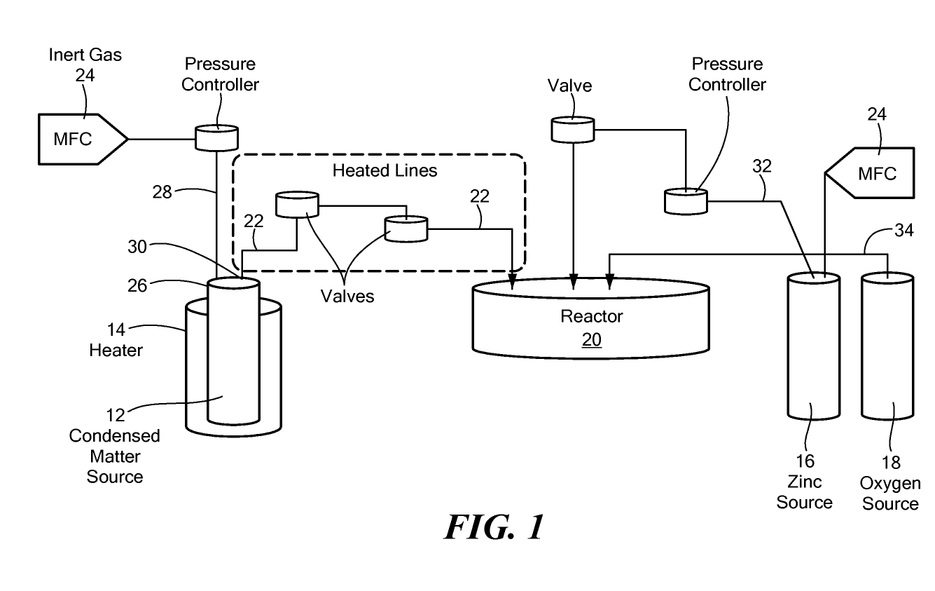

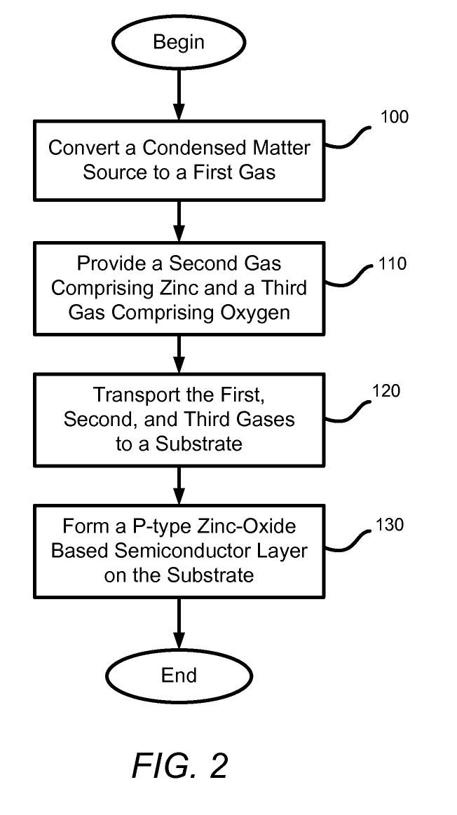

FIG. 1 schematically shows an illustrative MOCVD system 10 and FIG. 2 shows a MOCVD process according to embodiments of the present invention Referring to FIGS. 1 and 2, the MOCVD process begins at step 100, in which a condensed matter source 12 is converted to a first gas. A condensed matter source 12 may include a source in a solid phase, a liquid phase or a semisolid phase, such as a gel. A bubbler or heater 14 containing the condensed matter source 12 may be heated to above room temperature in order to convert the source 12 to the gas phase.

The condensed matter source 12 may, preferably, include non-halogenated and non-silylated complexes or may include halogenated or silylated complexes. When halogenated or silylated complexes are used, however, additional techniques may be needed in order to compensate for the unintentional incorporation of compensating donors, as discussed in more detail below. When using non-halogenated or non-silylated complexes, the material should have sufficient vapor pressure at reasonable elevated temperatures. For example, non-halogenated or non-silylated solid sources of Ag, Au and K may have a vapor pressure ranging from about 10⁻⁵ to about 10³ torr between about 30° C. and about 300° C., preferably from about 150° C. to about 300° C., and most preferably from about 200° C. to about 300° C. For example, the vapor pressure may be around 10³ torr at 200° C. for one type of material. Generally, the sublimation of Au and K occurs at higher temperatures relative to Ag sublimation because of much lower volatility of their ligands.

Examples of some non-halogenated and non-silylated precursors that may be used for the source 12 are listed below in Table 1 and some halogenated or silylated precursors that may be used are listed below in Tables 2 and 3, although others may be used.

TABLE 1
Non-halogenated and non-silylated precursors of Ag, Au and K

| Name | Variation |
|---|---|
| (R) silveracetylacetonate | R = Alkene and Alkyl |
| Silver Pivilate | |
| Silver trimethylacetate | |
| Dimethyl 1-2,4 pentadionate-Au | |
| (N,N″-diisopropylacetamindinato)Silver | Ag(i-PrNC(CH₃)N i-Pr) |
| Potassium Butoxide | |
| Triethylphosphine-Au-1-Diethyl- | |
| dithiocarbamate | |
| 2,2,6,6-Tetramethyl-3,5-heptanedionato | |
| potassium (KTHD) | |
| Dipivaloylmethanoatopotassium(KDPM) | |

TABLE 2
List of Halogenated or Silylated Silver and Gold Precursors

| Name | Variations | | |
|---|---|---|---|
| α-silver | α = | (β-diketonato) | |
| (bistrimethylsilyl) | | Hfac = hexafluoroacetyl | |
| acetylene | | Ttfac | |
| | | Btfac | |
| | | fod | |
| α-silver-vinyltriethlysilane | α = | Hfac | |
| α-silver-trialkylphosphine | α = | | (Cyclopentadienyl) |
| Ag (Cp)(PR₃) | | | (13-diketonato) |
| | | Hfac | |
| | | fod | |
| | | R = | Hydrocarbon e.g. |
| | | | Methyl group |
| | | | Ethyl group |

| | |
|---|---|
| Silver trifluoroacetate | Ag(COOCF₃) |
| Silver pentafluoropropionate | Ag(C₂F₅COO) and |
| | Ag(C₂F₅COO)PMe₃ |
| Dimethyl(1,1,1,trifluoro-2-4 | |
| pentadionate)Au | |
| Dimethyl(1,1,1-5,5,5, | |
| hexafluoro-2-4 | |
| pentadionate)Au | |
| Triethylphosphine-Au- | |
| Chloride | |

TABLE 3
List of Halogenated or Silylated Potassium Precursors

| Name | Variations |
|---|---|
| Potassium Hexafluorogermanante | K₂GeF₆ |
| Potassium Hexafluorosilicate | K₂SiF₆ |
| Potassium HexamethylDisilazide | KSi(CH₃)₃NSi(CH₃)₃ |
| Potassium Trimethlysilanolate | KOSi(CH₃)₃ |
| Potassium VinlyDImethlySilanolate | KOSi(CH₃)₂CHCH₂ |

For example, when using silver atoms for the p-type dopant, the vapor pressure of the silver-based condensed matter source or precursor may typically be between at least about 10⁻⁵ to 10³ torr. The conversion of the silver-based precursors may be achieved by heating the bubbler or heater 14 that contains one or more selected p-type dopant compounds to at or above the compound's sublimation temperature, but below its decomposition temperature. For example, for some silver-based compounds, the sublimation temperature may be between about 30° C. to about 205° C. and the decomposition temperature may be between about 80° C. to about 300° C. For instance, when using silver trifluoroacetate (CF₃COOAg) as the precursor, the heater 14 may be uniformly heated to an elevated temperature of about 60° C. (or higher) to ensure that significant vapor pressure of the precursor (e.g., ≧10⁻⁵ torr) is achieved even though the actual sublimation temperature of CF₃COOAg commences at around 30° C. in air. Similarly, when using silver trialkyphosphine-acetylacetonate (AcAcAgP₃) as the precursor, the heater 14 may be heated to a temperature of about 180° C. (or higher) to ensure that significant vapor pressure of the precursor (e.g., ≧10⁻¹ torr) is achieved even though the actual sublimation temperature of AcAcAgP₃ commences at around 80° C. in air. As known to those skilled in the art, the sublimation temperatures may be marginally different in a vacuum.

Due to the thermal processing conditions, a condensed matter source 12 may be adversely affected over time by the polymerization of the source's constituents. Typically, polymerization reduces the vapor pressure of the sources over a period of time. Embodiments of the present invention provide a way to minimize or reduce the polymerization of the condensed matter source 12. One method may include chemical techniques, such as incorporating inhibitors (e.g., quinones and/or oxygen) that inhibit or slow down the polymerization reaction. In addition, or alternatively, another method may include physical processes, such as the interspersing of inert particles with the condensed matter source material. For example, the inert particles may be made of a refractory nitride material (e.g., boron nitride, tungsten nitride) and/or a refractory oxide material (e.g., magnesium oxide, vanadium oxide, titanium oxide). When the source is in a solid phase, such as a powder, the inert particles may be interspersed with the powdered solid source and when the source is in a liquid or semisolid phase, the inert particles may be suspended in the source material. The inert particles may have any shape, e.g., spherical or otherwise, nanotube macroparticles, etc. When a powdered solid source is used, the inert particles may have a particle size distribution or dimension comparable to the particle size distribution of the powdered solid source. In general, benefits are usually obtained by increasing the surface area of the condensed matter source in order to improve the uniformity of the source's diffusion as well as help reduce the polymerization of the source's constituents.

In step 110, a second gas comprising zinc is provided from a zinc-based source 16 and a third gas comprising oxygen is provided from an oxygen-based source 18. The zinc-based source 16 and the oxygen-based source 18 are typically supplied in the gas phase, although the source may be in a solid, liquid, or semisolid phase.

In step 120, the first gas, second gas, and third gas are transported to one or more substrates (not shown) located within a reactor chamber 20. As known to those skilled in the art, the substrate may be a wafer processed in a variety of ways and may include a variety of materials. For ZnO films, the substrate preferably includes ZnO, although other materials may be used. For example, the substrate may be a zinc oxide alloy (e.g., zinc magnesium oxide), silicon, silicon carbide, gallium nitride, sapphire, a glass material, a plastic material, etc.

Transport of the first gas species is achieved by heating gas lines 22 to an elevated temperature in order to limit or prevent condensation of the converted species during transport prior to delivery into a reactor chamber 20. The elevated temperature should be at least the minimum temperature of actual conversion/sublimation (e.g., 30° C. in the case of CF₃COOAg, 80° C. in the case of AcAcAgP₃) and preferably higher. For example, the elevated temperature gas lines 22 may be maintained at approximately the same temperature as the bubbler 14 (e.g., 60° C. in the case of CF₃COOAg, 180° C. in the case of AcAcAgP₃) or higher. For instance, the heated gas lines 22 may be maintained at about 190° C. in the case of AcAcAgP₃.

An inert gas 24, such as argon, may be supplied into the heated bubbler 14 through an inlet port 26 via gas lines 28 and allowed to exit through an outlet port 30 into the heated gas lines 22. The inert gas 24 may or may not be heated to an elevated temperature in gas lines 28 prior to entering the heater 14. In addition, or alternatively, an inert gas 24 may be supplied into the zinc-based source 16 and/or the oxygen-based source 18 or may be supplied into the gas lines 32 and 34. The inert gas 24 may be used to help transport the first gas, the second gas, and/or the third gas. The elevated temperature gas transport lines 22 may have valves and gauges that utilize special seals (e.g., such as polyimide and stainless steel), which may enable the flow regulation of the transported species within the temperature range of interest. Gas lines 32 and 34 transport the second gas and the third gas, respectively, to the reactor chamber 20. The elevated temperature gas lines 22 may be separate from the gas lines 32 and 34 containing the precursor of the matrix elements, Zn and O₂, to prevent any premature reactions. When significant pressures are used, the diameter of the gas lines, 22, 32, 34 may need to be increased in order to maintain an acceptable pressure within the gas lines. For example, when the pressure ranges from about 300 torr to about 500 torr or even 1000 torr the diameter of the gas lines may be increased from about ¼ inch to about ½ inch or even 1 inch diameter tubing, although other methods may be used to regulate these higher pressures.

As known by those skilled in the art, the deposition process is conducted in the reactor chamber 20 where the first gas comprising the organometallic precursor is used in combination with the second and third gases. One or more additional gases may also be used, e.g., other organometallic precursors, reactive gases, inert carrier gases, etc. Control of the process gas composition may be accomplished using mass-flow controllers, valves, etc., as known by those skilled in the art. The one or more substrates are typically heated to an elevated temperature in the reactor chamber 20. As the first, second and third gases enter into the reactor 20, pyrolysis of the precursor complexes occurs either in the gas mixture or at the surface of the substrate when the gas mixture contacts the heated substrate surface. In step 130, a p-type zinc-oxide based semiconductor layer is formed on the one or more substrates when the p-type dopant from the first gas is incorporated into the ZnO layer.

As mentioned above, when using non-halogenated and non-silylated complexes for the condensed matter source material, atomic concentrations of the p-type dopant of about 10¹⁵ to about 10²² cm⁻³ (or more) may be realized without any additional processes or processing. When using halogenated or silylated complexes, additional techniques that limit the unintentional incorporation of compensating donors into the film may be needed. These techniques may include reducing the amount of unwanted donor species before the species are incorporated into the film and/or after incorporation.

One method may include the elevated temperature heating of the substrate (e.g., ≧400° C.) so that chemisorption of these deleterious donor species is discouraged from the surface. This allows pyrolysis of the gaseous species to occur on the surface of the substrate when a sufficient kT energy is transferred to incident complexes and also allows rapid desorption of the unwanted volatile species from the film's growth front.

For example, when a solid CF₃COOAg complex is used for the source 12, Ag is incorporated into the ZnO layers along with the unintentional incorporation of carbon (C) and fluorine (F). The incorporation of F compensates for the Ag-acceptors since F is a donor in ZnO. Heating the substrate during growth of the ZnO film may provide sufficient thermal energy to be transferred so as to allow the pyrolysis of CF₃COOAg as well at the desorption of the residual fluorine containing ligand from the growth surface. A temperature range of between about 400° C. to about 1000° C. may facilitate this effect, preferably greater than about 700° C.

In addition, a greater net incorporation of Ag into the epitaxial layer may be possible because the chemisorption rate of Ag (defined as R_{Ag} below) is greater than the chemisorption rate of F (defined as R_{F} below) due to the fact that the surface sticking coefficient of F, η_{F}, is less than the sticking coefficient of Ag, η_{Ag}, as described by the chemisorption rates below. These rates may be dependent upon F and Ag, with each species described by the expressions below:

R_{Ag}=η_{Ag}*|Ag_X|

R_{F}=η_{F}*|F_Y|

wherein |Ag_X| and |F_Y| are the concentrations of species bearing Ag and F, respectively, resulting from the pyrolysis of CF₃COOAg as described in the example pyrolysis reactions below:

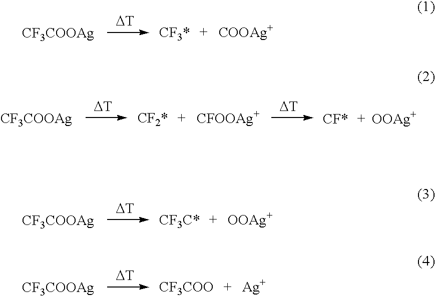

where X and Y are constituents of the ligand chain example in equation 3 above, where X═OO and Y═CC*. The aforementioned configuration may also be possible because of the heavier atomic weight of Ag or Ag—O complexes relative to F or CF₃ complexes and also because of the higher thermodynamic stability of Ag—O—Zn complexes relative to F—O—Zn complexes. In this case, the substrate may be heated to an elevated temperature of between about 700° C. to about 850° C. The sticking coefficient of fluorine bound ligands to the film's surface may be reduced at these temperatures, reducing the solid-state incorporation of fluorine into the ZnO layers.

Another method of reducing the amount of unwanted donor species may include the introduction of a surfactant species that has a high affinity for the donor species so that the surfactant binds the species and/or retains it in a gas phase after pyrolysis. For example, in the case of the halogens, a suitable surfactant may include boron or lithium, which may be introduced into the reactor 20 to bind the deleterious halogen, e.g., as BF₂, BCl₃. For instance, halogenated radicals such as CF₃* may reacted with a boron gas stream supplied by, for example, boron ethoxide or t-butoxide, borazine, boron allyloxide, triethyl boron, etc., although other compounds may be used, resulting in a compound containing the species CF₃B. The surfactant thus inhibits solid state incorporation of the donor species into the ZnO film by retaining the species in the gas phase or limits the electrical or electronic activity of these dopants within the ZnO film by retaining them in bound form even when incorporated into the film. The surfactant may be introduced into the reactor 20 via gas lines (not shown) that are separate from gas lines 22, 32 and 34.

Another method of reducing the amount of unwanted donor species may include reducing the concentration of donor species from the bulk of the ZnO film after the species are incorporated into the film. This may be accomplished by a high temperature anneal process and/or a moderate temperature and high pressure anneal process that allows the donor species to diffuse out of the film or away from the film's surface toward the back of the substrate. For example, in the case of fluorine, an effective annealing process may include annealing at a temperature between about 500° C. to about 1400° C. in an ambient (e.g., air, oxygen, forming gas, or an inert gas, such as argon or nitrogen) at pressures ranging from about 0.1 mbar to about 2.4 kbar. One embodiment includes annealing at 1000° C. at 1 atm of oxygen isochronically for greater than about 1 hour, and preferably, about 3 hours.

Another method of reducing the concentration of unwanted donor species from the bulk film may include an impurity gettering process. Impurity gettering may be facilitated by the intentional introduction of impurity gettering defects, such as a network of dislocations and grain boundaries, to the back surface of the substrate (i.e., the surface of the substrate that does not or will not have the deposited ZnO film). Gettering may take advantage of the different diffusion coefficients of the impurity atoms within the bulk of the film relative to those occurring along dislocation and grain boundaries. For example, a network of dislocations may be introduced to the back surface of the substrate by mechanical abrasion. Upon elevated temperature processing, the donor impurities (e.g., fluorine and silicon) may migrate and diffuse toward these defects on the other side of the substrate, resulting in a net concentration of acceptors within the bulk deposited film.

Although the above discussion discloses various exemplary embodiments of the invention, it should be apparent that those skilled in the art can make various modifications that will achieve some of the advantages of the invention without departing from the true scope of the invention.

What is claimed is:

1. A method of metalorganic chemical vapor deposition, the method comprising:
converting a condensed matter source to provide a first gas, the source including at least one element selected from the group consisting of gold, silver and potassium;
providing a second gas comprising zinc and a third gas comprising oxygen;
transporting the first gas, the second gas, and the third gas to a substrate; and
forming a p-type zinc-oxide based semiconductor layer on the substrate.

2. A method according to claim 1, wherein the condensed matter source is a non-halogenated and non-silylated source.

3. A method according to claim 2, wherein the non-halogenated and non-silylated condensed matter source is in a solid phase, and converting includes subliming the source.

4. A method according to claim 3, wherein the source has a vapor pressure ranging from about 10⁻⁵ to about 10³ torr between about 30° C. to about 300° C.

5. A method according to claim 3, wherein transporting the first gas includes heating transport lines of the first gas to a temperature of about the source's sublimation temperature or greater.

6. A method according to claim 1, wherein the source includes a polymerization inhibitor.

7. A method according to claim 6, wherein the polymerization inhibitor includes inert particles.

8. A method according to claim 7, wherein the source is a powder interspersed with the inert particles, the inert particles having a size distribution that is of the same order of magnitude as that of the powder.

9. A method according to claim 7, wherein the source is a liquid or a gel and the inert particles are suspended in the liquid or the gel.

10. A method according to claim 6, wherein the polymerization inhibitor is selected from the group consisting of quinones and oxygen.

11. A method according to claim 1, further comprising providing a fourth gas including a surfactant that reacts with the first gas, wherein transporting includes transporting the first gas, the second gas, the third gas, and the fourth gas to the substrate.

12. A method according to claim 11, wherein the surfactant includes boron.

13. A method according to claim 1, wherein the condensed matter source includes a halogen or silicon.

14. A method according to claim 13, wherein the condensed matter source is in a solid phase, and converting includes subliming the source.

15. A method according to claim 14, wherein the source has a vapor pressure ranging from about 10⁻⁵ to about 10³ torr between about 30° C. and about 300° C.

16. A method according to claim 13, wherein the substrate is heated in an elevated temperature environment between about 700° C. to about 850° C.

17. A method according to claim 13, further comprising annealing the p-type zinc-oxide based semiconductor layer in an elevated temperature environment for a period of time so that at least a portion of the halogen or silicon diffuses out of the layer.

18. A method according to claim 17, wherein the elevated temperature environment is between about 500° C. to about 1400° C.

19. A method according to claim 17, wherein the elevated temperature environment is between about 900° C. to about 1100° C. and the period of time is greater than about 1 hour.

20. A method according to claim 17, wherein annealing is performed at a pressure ranging from about 0.1 mbar to about 2.4 kbar.

21. A method according to claim 17, wherein annealing is performed in an ambient that includes at least one selected from the group consisting of an inert gas, air, nitrogen, and oxygen.

22. A method according to claim 13, wherein the substrate includes a first surface and a second surface, and forming a p-type zinc-oxide based semiconductor layer occurs on the first surface, the method further comprising:
abrading the second surface of the substrate; and
annealing the substrate in an elevated temperature environment for a period of time so that at least a portion of the halogen or silicon diffuses away from the first surface towards the second surface.

23. A method of depositing a p-type zinc-oxide based semiconductor layer onto a substrate by a metalorganic chemical vapor deposition technique, the method comprising:
converting a non-halogenated and non-silylated condensed matter source to a first gas that provides a p-type dopant, wherein the condensed matter source includes at least one element selected from the group consisting of gold, silver, and potassium and has a vapor pressure ranging from about 10⁻⁵ to about 10³ torr between about 30° C. to about 300° C.;
supplying reaction gases including the first gas, a second gas comprising zinc, and a third gas comprising oxygen; and
transporting the reaction gases to a surface of a substrate to grow the p-type zinc-oxide based semiconductor layer.

24. A method according to claim 23, wherein the non-halogenated and non-silylated condensed matter source is in a solid phase, and converting includes subliming the source.

25. A method according to claim 24, wherein supplying the first gas includes heating transport lines of the first gas to a temperature of about the source's sublimation temperature or greater.

26. A method according to claim 23, wherein the source includes a polymerization inhibitor.

27. A method according to claim 26, wherein the polymerization inhibitor includes inert particles.

28. A method according to claim 27, wherein the source is a powder interspersed with the inert particles, the inert particles having a size distribution that is of the same order of magnitude as that of the powder.

29. A method according to claim 27, wherein the source is a liquid or a gel and the inert particles are suspended in the liquid or the gel.

30. A method according to claim 26, wherein the polymerization inhibitor is selected from the group consisting of quinones and oxygen.

31. A method of forming a p-type zinc-oxide based semiconductor layer by metalorganic chemical vapor deposition, the method comprising:
converting a condensed matter source to provide a first gas comprising a halogen or silicon, the source including at least one element selected from the group consisting of gold, silver, and potassium;
providing a second gas comprising zinc and a third gas comprising oxygen;
transporting the first gas, the second gas, and the third gas to the substrate to form a zinc-oxide based film; and
annealing the zinc-oxide based film in an elevated temperature environment for a period of time so that at least a portion of the halogen or silicon diffuses out of the film to produce the p-type zinc-oxide based semiconductor layer.

32. A method according to claim 31, wherein the condensed matter source is in a solid phase, and converting includes subliming the source.

33. A method according to claim 32, wherein transporting the first gas includes heating transport lines of the first gas to a temperature of about the source's sublimation temperature or greater.

34. A method according to claim 31, wherein the source includes a polymerization inhibitor.

35. A method according to claim 34, wherein the polymerization inhibitor includes inert particles.

36. A method according to claim 35, wherein the source is a powder interspersed with the inert particles, the inert particles having a size distribution that is of the same order of magnitude as that of the powder.

37. A method according to claim 35, wherein the source is a liquid or a gel and the inert particles are suspended in the liquid or the gel.

38. A method according to claim 34, wherein the polymerization inhibitor is selected from the group consisting of quinones and oxygen.

39. A method according to claim 31, further comprising providing a fourth gas including a surfactant that reacts with the first gas, wherein transporting includes transporting the first gas, the second gas, the third gas, and the fourth gas to the substrate to form a zinc-oxide based film.

40. A method according to claim 39, wherein the surfactant includes boron.

41. A method according to claim 31, wherein the elevated temperature environment is between about 500° C. to about 1400° C.

42. A method according to claim 31, wherein the elevated temperature environment is between about 900° C. to about 1100° C. and the period of time is greater than about 1 hour.

43. A method according to claim 31, wherein annealing is performed at a pressure ranging from about 0.1 mbar to about 2.4 kbar.

44. A method according to claim 31, wherein annealing is performed in an ambient that includes at least one selected from the group consisting of an inert gas, air, and oxygen.

45. A method of forming a p-type zinc-oxide based semiconductor layer on a substrate by metalorganic chemical vapor deposition, the method comprising:
heating the substrate in an elevated temperature environment between about 700° C. to about 850° C.;
converting a condensed matter source to provide a first gas comprising a halogen or silicon, the source including at least one element selected from the group consisting of gold, silver, and potassium;
providing a second gas comprising zinc and a third gas comprising oxygen; and
transporting the first gas, the second gas, and the third gas to a surface of the substrate to grow the p-type zinc-oxide based semiconductor layer.

46. A method according to claim 45, wherein the condensed matter source is in a solid phase, and converting includes subliming the source.

47. A method according to claim 45, further comprising providing a fourth gas including a surfactant that reacts with the first gas, transporting includes transporting the first gas, the second gas, the third gas, and the fourth gas to the substrate to grow the p-type zinc-oxide based semiconductor layer.

48. A method according to claim 47, wherein the surfactant includes boron.

49. A method according to claim 45, further comprising annealing the p-type zinc-oxide based semiconductor layer in an elevated temperature environment for a period of time so that at least a portion of the halogen or silicon diffuses out of the layer.

50. A method of metalorganic chemical vapor deposition, the method comprising:
converting a condensed matter source to provide a first gas, the source including at least one p-type dopant element;
providing a second gas comprising zinc and a third gas comprising oxygen;
transporting the first gas, the second gas, and the third gas to a substrate; and
forming a p-type zinc-oxide based semiconductor layer on the substrate.

51. A method according to claim 50, wherein the p-type dopant element includes at least one element selected from the group consisting of gold, silver, and potassium.

52. A metalorganic chemical vapor deposition system for p-type zinc oxide comprising:
a condensed matter source including at least one p-type dopant element;
a first source comprising zinc;
a second source comprising oxygen;
a chemical vapor deposition reactor chamber connected to the condensed matter source, the first source, and the second source; and
a heated transport line connecting the condensed matter source to the chemical vapor deposition reactor chamber.

53. The system of claim 52, further comprising:
a heater containing the condensed matter source.

54. The system of claim 52, wherein the at least one p-type dopant element is selected from the group consisting of gold, silver, and potassium.
